(19) United States
(12) Patent Application Publication
(10) Pub. No.: US 2007/0049062 A1
(43) Pub. Date: Mar. 1, 2007

(54) Electric connector for connecting an expansion card to a circuit board

(75) Inventor: Chien-Chih Ho, Keelung City (TW)

Correspondence Address: TROXELL LAW OFFICE PLLC;SUITE 1404, 5205 LEESBURG PIKE, FALLS CHURCH, VA, 22041, US

(73) Assignee: Lotes Co., Ltd.

(21) Appl. No.: 11/377,300

(22) Filed: Mar. 17, 2006

(30) Foreign Application Priority Data
Sep. 1, 2005 (CN) 200520063779.8

(51) Int. Cl. H05K 1/00

(52) U.S. Cl. 439/65

(57) ABSTRACT

An electric connector for connecting an expansion card to a circuit board comprises an elongated insulating body and an array of conducting terminals. The insulating body has a central insertion slot for receiving an expansion card; the central insertion slot further includes a plurality of terminal reception holes on two lateral sides thereof, which are connected to the central insertion slot. Two inner lateral walls of the central insertion slot further includes a plurality of projection pairs extended inwardly to support against two opposite lateral walls of the inserted expansion card. Thereby, the clipping force between the connector and the card will be enhanced, and the phenomenon of “folded pins” will be prevented.

### BACKGROUND OF THE INVENTION

(a) Field of the Invention

The present invention relates to electric connectors for connecting an expansion card to a circuit board, more particularly to an electric connector for connecting an expansion card to a circuit board wherein the clipping force between the card and the connector is enhanced, so as to prevent the problem of mis-folded conducting pins.

(b) Description of the Prior Art

An electric connector for connecting an expansion card to a circuit board of the prior art comprises an insulting body and a plurality of conducting terminals in the insulating body. The insulating body further includes an elongate central insertion slot for containing an expansion card. To assure the insertion of an electric connector for connecting an expansion card to a circuit board into the central insertion slot even when the central insertion slot is slightly deformed, the width of the central insertion slot is designed to be larger than the thickness of the expansion card, which will result in two problems. The first is the insufficient clipping force between the expansion card and the insulating body due to a lack in precision alignment between them, influencing the electric conduction between. The second problem is the inevitable non-symmetric attachment of the expansion card on one of the inner lateral wall of the central insertion slot that causes a downward shift of some of the conducing terminals. In the worst case, some conducing terminals could be thereby folded and cannot be contacted properly with corresponding conducting pieces of the expansion card.

Therefore, it is necessary to invent an electric connector for connecting an expansion card to a circuit board wherein the electric conduction is assured.

### SUMMARY OF THE INVENTION

The primary objective of the present invention is to provide an electric connector for connecting an expansion card to a circuit board wherein the clipping force between the card and the connector is enhanced, and the phenomenon of “folded pins” can be avoided.

To achieve the primary objective, the electric connector for connecting an expansion card to a circuit board of the present invention comprises an elongated insulating body having a central insertion slot for holding an expansion card and an array of conducting terminals respectively housed in terminal reception holes distributed along two lateral sides of the central insertion slot. The terminal reception holes are connected to the central insertion slot. The connector further comprises a plurality of projections extended from the inner lateral walls of the central insertion slot toward the inner space of the central insertion slot for supporting against the expansion card.

Compared with the current technologies, the electric connector for connecting an expansion card to a circuit board of the present invention has a plurality of projections within the central insertion slot for confining the expansion card, which will enhance the clipping force between the connector and the card and prevent the phenomenon of “folded pins”.

The various objects and advantages of the present invention will be more readily understood from the following detailed description when read in conjunction with the appended drawings.

### BRIEF DESCRIPTION OF THE DRAWINGS

FIG. 1 is a side view of an electric connector for connecting an expansion card to a circuit board of the present invention.

FIG. 2 is a top view of the electric connector for connecting an expansion card to a circuit board in FIG. 1.

FIG. 3 is a front view of the electric connector for connecting an expansion card to a circuit board in FIG. 1 from the right.

FIG. 4 is the A-A side cross-sectional view of the electric connector for connecting an expansion card to a circuit board corresponding to FIG. 2.

FIG. 5 is an enlarged view of the local portion labeled by D in FIG. 4.

FIG. 6 is an enlarged view of the local portion labeled by E in FIG. 4.

FIG. 7 is the C-C front cross-sectional view of the electric connector for connecting an expansion card to a circuit board corresponding to FIG. 2.

FIG. 8 is the cross-sectional view of the electric connector for connecting an expansion card to a circuit board in FIG. 7, wherein an expansion card is inserted.

FIG. 9 is a local enlarged view of the electric connector for connecting an expansion card to a circuit board in FIG. 7 for indicating the electric connection.

### DETAILED DESCRIPTION OF THE PREFERRED EMBODIMENTS

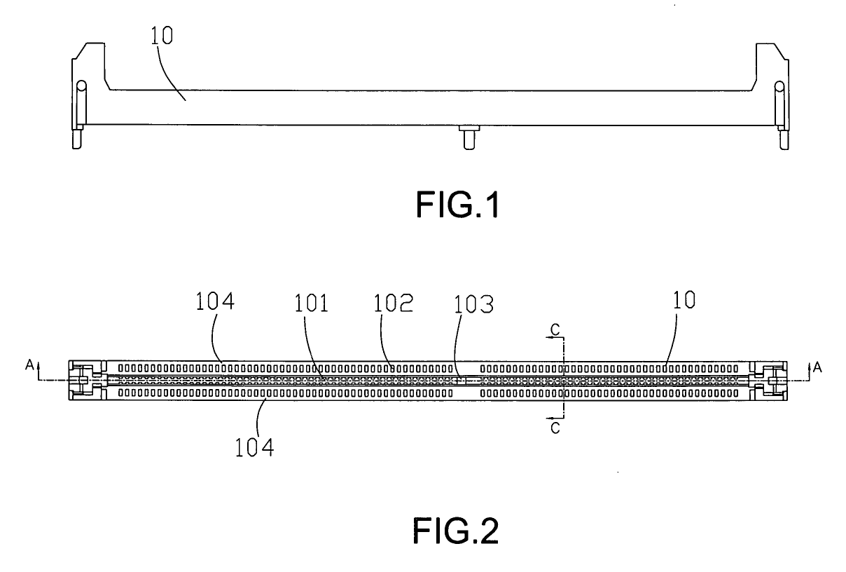

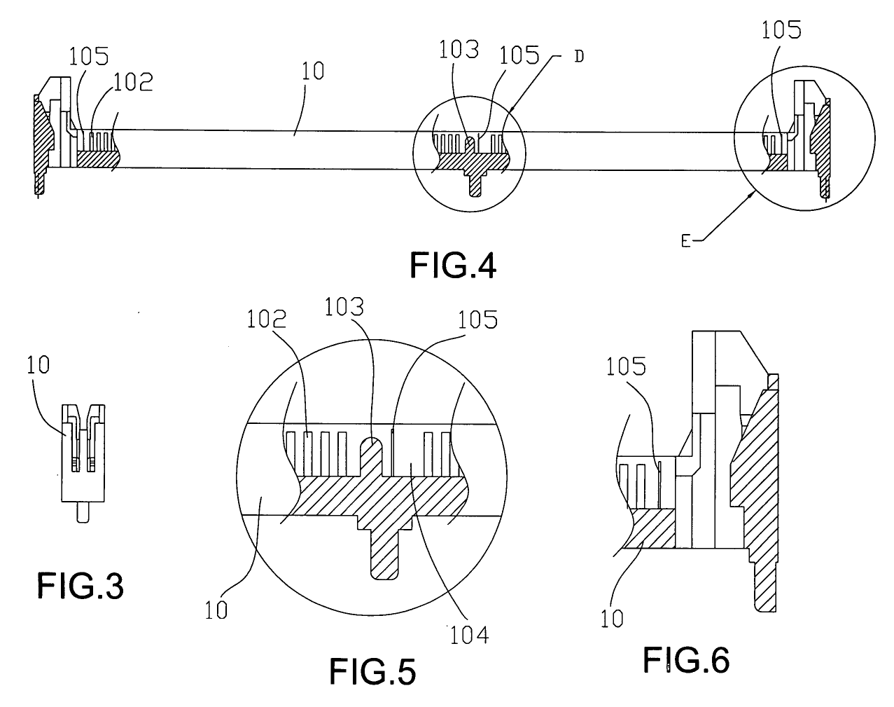

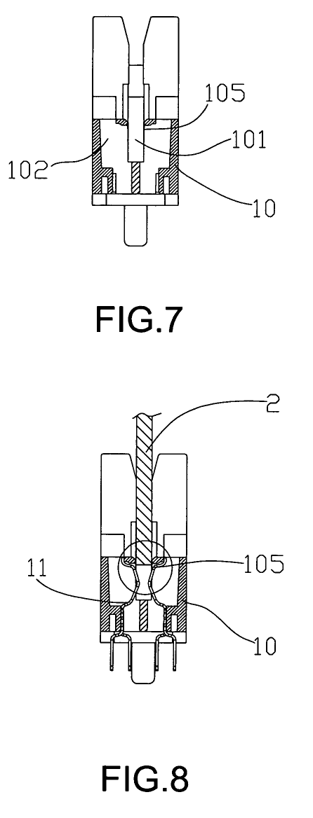

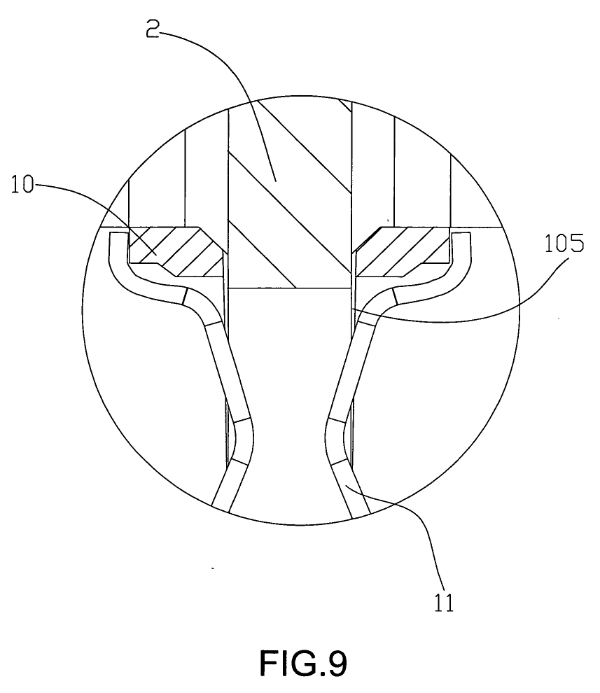

Referring to FIGS. 1 to 9, an electric connector 1 for holding an expansion card according to the present invention is mounted on a circuit board for connecting an expansion card 2. The electric connector for holding an expansion card 1 comprises an insulating body 10 and an array of conducting terminals 11.

The insulating body 10 is an elongated body having a central insertion slot 101 for receiving the expansion card 2 and two arrays of terminal reception holes 102 each on one side thereon for housing corresponding pieces of the conducting terminal array 11. The terminal reception holes 102 are connected to the central insertion slot 101. The central insertion slot 101 further includes a fool proof device 103 for preventing a wrong insertion of the expansion card 2 into the central insertion slot 101. There are a plurality of inwardly extended, strip-like projections 105 formed on inner lateral walls 104 of the central insertion slot 101. The extension direction of the projections 105 is perpendicular to the longitude of the central insertion slot 101, and each of the projections 105 has the same height. The minimum number of pairs of projections 105 is three, one at the center of the central insertion slot 101 and two respectively at the right and left ends. One of the pairs of the projections 105 are adjacent to the fool proof device 103. Each of the pairs of the projections 105 has a spacing small enough to clip the expansion card 2 and are deformable when the expansion card 2 is intruded. Thereby, the pairs of the projections 105 can provide a precision alignment and confinement of the expansion card 2, which will prevent tilting of the card toward either side of the connector. Further, the clipping force between the card and the connector is enhanced, assuring normal electric conduction and between the card and the connector and preventing the phenomenon of “folded pins”.

The present invention is thus described, and it will be obvious that the same may be varied in many ways. Such variations, such as the variations in the shape of the projections within the central insertion slot as projected dots or wedges, are not to be regarded as a departure from the spirit and scope of the present invention, and all such modifications as would be obvious to one skilled in the art are intended to be included within the scope of the following claims.

What is claimed is:

1. An electric connector for connecting an expansion card to a circuit board, comprising:
an elongated insulating body with a central insertion slot for receiving an expansion card, said central insertion slot further including a plurality of terminal reception holes on two lateral sides thereof, said terminal reception holes being connected to said central insertion slot, two inner lateral walls of said central insertion slot further including a plurality of projection pairs extended inwardly to support against two opposite lateral walls of said expansion card; and
an array of conducting terminals.

2. The electric connector for connecting an expansion card to a circuit board of claim 1 wherein said projection pairs are located at the center and both ends of said central insertion slot.

3. The electric connector for connecting an expansion card to a circuit board of claim 1 wherein said central insertion slot further comprises a fool proof mechanism; one of said projection pairs being located nearby said fool proof mechanism.

4. The electric connector for connecting an expansion card to a circuit board of claim 1 wherein the number of said projection pairs is at least three.

5. The electric connector for connecting an expansion card to a circuit board of claim 4 wherein each of said projection pairs has an equal spacing.

6. The electric connector for connecting an expansion card to a circuit board of claim 1 wherein each of said projection pairs is selected from stripe-like projection and wedged projection.

7. The electric connector for connecting an expansion card to a circuit board of claim 6 wherein a longitudinal direction to which said projection pairs extend is perpendicular to the longitude of said central insertion slot.

8. The electric connector for connecting an expansion card to a circuit board of claim 1 wherein each of said projection pairs is located between two adjacent conducting terminals.
